(19) United States
(12) Patent Application Publication
(10) Pub. No.: US 2024/0072005 A1
(43) Pub. Date: Feb. 29, 2024

(54) SEMICONDUCTOR PACKAGE

(71) Applicant: Samsung Electronics Co, Ltd., Suwon-si (KR)

(72) Inventor: Kyung Don MUN, Suwon-si (KR)

(73) Assignee: Samsung Electronics Co., Ltd., Suwon-si (KR)

(21) Appl. No.: 18/299,896

(22) Filed: Apr. 13, 2023

(30) Foreign Application Priority Data
Aug. 31, 2022 (KR) 10-2022-0110113

(51) Int. Cl. H01L 25/065; H01L 21/56; H01L 23/31; H01L 23/373; H01L 23/498; H01L 23/538; H10B 80/00

(52) U.S. Cl. CPC H01L 25/0657; H01L 21/563; H01L 23/3157; H01L 23/373; H01L 23/49827; H01L 23/49838; H01L 23/538; H10B 80/00; H01L 24/16; H01L 2224/16221; H01L 2225/1094

(57) ABSTRACT

A semiconductor package includes a substrate, a first chip stack including a plurality of first semiconductor chips sequentially stacked on the substrate, and a second chip stack including a plurality of second semiconductor chips sequentially stacked on the first chip stack, and first and second pluralities of thermal conductive layers. The first thermal conductive layers are each between the substrate and the first chip stack, or between adjacent first semiconductor chips. The second thermal conductive layers are each between the first chip stack and the second chip stack, or between adjacent second semiconductor chips. A thermal conductivity of a second thermal interface material of the second thermal conductive layers is greater than a thermal conductivity of a first thermal interface material of the first thermal conductive layers, and a stiffness of the first thermal interface material is greater than a stiffness of the second thermal interface material.

### CROSS-REFERENCE TO RELATED APPLICATION

This U.S. nonprovisional application claims priority under 35 U.S.C. § 119 to Korean Patent Application No. 10-2022-0110113 filed on Aug. 31, 2022 in the Korean Intellectual Property Office, the disclosure of which is hereby incorporated by reference in its entirety.

### BACKGROUND

The inventive concepts relate to a semiconductor package, including a stacked semiconductor package in which a plurality of semiconductor chips are stacked on a substrate.

With the development of the electronic industry, electronic products have increasing demands for high performance, high speed, and compact size. To meet the trend, there has recently been developed a packaging technology in which a plurality of semiconductor chips are mounted in a single package.

A plurality of adhesive members are used to stack a plurality of devices, and an increase in the number of stacked devices causes various problems.

### SUMMARY

Some example embodiments of the inventive concepts provide a semiconductor package with enhanced structural stability.

Some example embodiments of the inventive concepts provide a semiconductor package with improved thermal stability.

The inventive concepts are not limited to those mentioned above, and other objects which have not been mentioned above will be clearly understood to those skilled in the art from the following description.

According to some example embodiments of the inventive concepts, a semiconductor package includes a substrate including a plurality of vias, a first chip stack on the substrate, the first chip stack including a plurality of first semiconductor chips sequentially stacked on the substrate, and a second chip stack on the first chip stack, the second chip stack including a plurality of second semiconductor chips sequentially stacked on the first chip stack. The package includes a plurality of first thermal conductive layers, a first one of the plurality of first thermal conductive layers between the substrate and the first chip stack, and at least a second one of the plurality of first thermal conductive layers between first semiconductor chips that are adjacent to each other. The package includes a plurality of second thermal conductive layers, a first one of the plurality of second thermal conductive layers between the first chip stack and the second chip stack, and at least a second one of the plurality of second thermal conductive layers between second semiconductor chips that are adjacent to each other. The first thermal conductive layers include a first thermal interface material, the second thermal conductive layers include a second thermal interface material, a thermal conductivity of the second thermal interface material is greater than a thermal conductivity of the first thermal interface material, and a stiffness of the first thermal interface material is greater than a stiffness of the second thermal interface material.

According to some example embodiments of the inventive concepts, a semiconductor package includes a substrate, a plurality of semiconductor chips sequentially stacked on the substrate, a plurality of chip terminals connecting the substrate to a lowermost one of the semiconductor chips and connecting neighboring semiconductor chips to each other, the chip terminals on central portions of the semiconductor chips with respect to a plan view, and a plurality of non-conductive layers surrounding the chip terminals. The package includes a plurality of thermal conductive layers, a first one of the plurality of thermal conductive layers between the substrate and the lowermost one of the semiconductor chips, and at least a second one of the plurality of thermal conductive layers between semiconductor chips that are adjacent to each other. The thermal conductive layers include a plurality of first thermal conductive layers, a first one of the plurality of first thermal conductive layers between the substrate and the lowermost one of the semiconductor chips, and at least a second one of the plurality of first thermal conductive layers between lower ones of the semiconductor chips, and a plurality of second thermal conductive layers between upper ones of the semiconductor chips. A thermal conductivity of the second thermal conductive layers is greater than a thermal conductivity of the first thermal conductive layers.

According to some example embodiments of the inventive concepts, a semiconductor package includes a substrate including a plurality of vias, a first chip stack mounted on the substrate, the first chip stack including a plurality of first semiconductor chips sequentially stacked on the substrate, and a second chip stack mounted on a top surface of the first chip stack, the second chip stack including a plurality of second semiconductor chips sequentially stacked on the first chip stack. The package includes a plurality of first thermal conductive layers, a first one of the plurality of first thermal conductive layers between the substrate and the first chip stack, and at least a second one of the plurality of first thermal conductive layers between first semiconductor chips that are adjacent to each other, the first thermal conductive layers including a first thermal interface material. The package includes a plurality of second thermal conductive layers, a first one of the plurality of second thermal conductive layers between the first chip stack and the second chip stack, and at least a second one of the plurality of second thermal conductive layers between second semiconductor chips that are adjacent to each other, the second thermal conductive layers including a second thermal interface material. The package includes a molding layer on the substrate, the molding layer covering the first chip stack and the second chip stack. The first thermal interface material and the second thermal interface material include aluminum oxide, and an amount of the aluminum oxide in the second thermal interface material is greater than an amount of the aluminum oxide in the first thermal interface material.

### BRIEF DESCRIPTION OF THE DRAWINGS

FIG. 1 illustrates a cross-sectional view showing a semiconductor package according to some example embodiments of the inventive concepts.

FIGS. 2 and 3 illustrate conceptual diagrams showing a thermal interface material according to some example embodiments of the inventive concepts.

FIG. 4 illustrates a graph of thermal conductivity versus volume of filler content in a thermal interface material according to some example embodiments of the inventive concepts.

FIG. 5 illustrates a cross-sectional view showing a semiconductor package according to some example embodiments of the inventive concepts.

FIG. 6 illustrates a conceptual diagram showing a thermal interface material according to some example embodiments of the inventive concepts.

FIG. 7 illustrates a cross-sectional view showing a semiconductor package according to some example embodiments of the inventive concepts.

FIG. 8 illustrates a cross-sectional view showing a semiconductor module according to some example embodiments of the inventive concepts.

### DETAILED DESCRIPTION

In this description, like reference numerals may indicate like components. The following will now describe a semiconductor package and its fabrication method according to the inventive concepts.

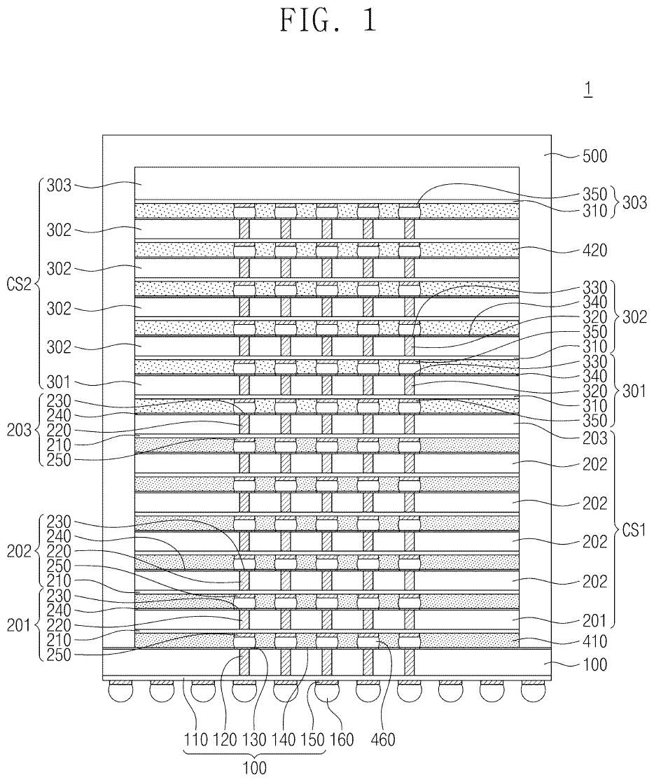

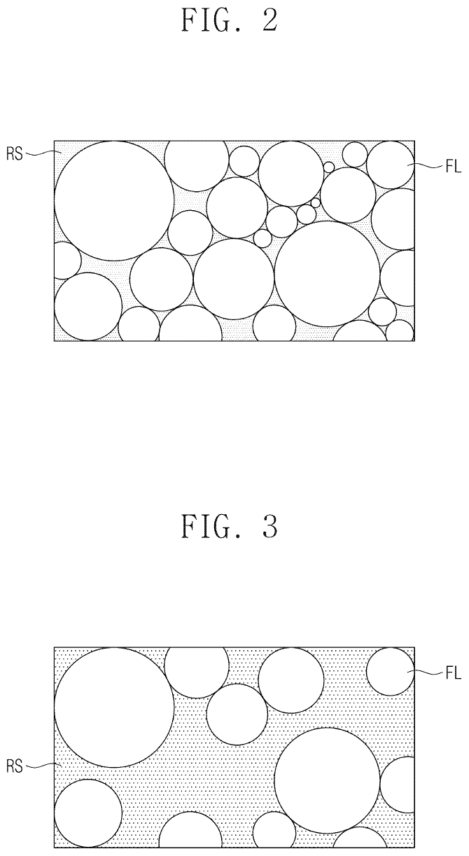

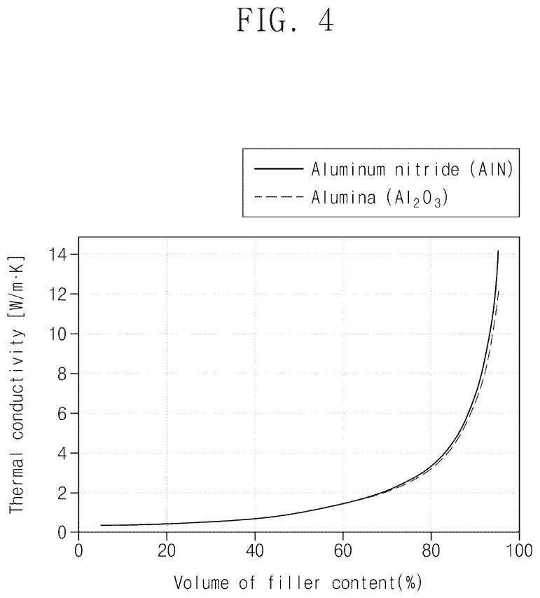

FIG. 1 illustrates a cross-sectional view showing a semiconductor package according to some example embodiments of the inventive concepts. FIGS. 2 and 3 illustrate conceptual diagrams showing a thermal interface material according to some example embodiments of the inventive concepts. FIG. 4 illustrates a graph of thermal conductivity versus volume of filler content in a thermal interface material according to some example embodiments of the inventive concepts.

Referring to FIG. 1, a semiconductor package 1 may include a base substrate 100, a first chip stack CS1, a second chip stack CS2, a first thermal conductive layer 410, and a second thermal conductive layer 420.

The base substrate 100 may be provided. The base substrate 100 may include an integrated circuit therein. For example, the base substrate 100 may be a semiconductor chip including an electronic device such as a transistor. For example, the base substrate 100 may be a wafer-level die formed of a semiconductor such as silicon (Si). FIG. 1 depicts that the base substrate 100 is a semiconductor chip, but the inventive concepts are not limited thereto.

According to some example embodiments of the inventive concepts, the base substrate 100 may be a substrate, such as a printed circuit board (PCB), which does not include an electronic device such as a transistor. A silicon wafer may have a thickness less than that of a printed circuit board (PCB). The following will describe an example embodiment in which the base substrate 100 and a semiconductor chip are the same component.

The semiconductor chip 100 may include a first circuit layer 110, a first via 120, a first upper pad 130, a first protection layer 140, and a first lower pad 150.

The first circuit layer 110 may be provided on a bottom surface of the semiconductor chip 100. The first circuit layer 110 may include the integrated circuit. For example, the first circuit layer 110 may be a memory circuit, a logic circuit, or a combination thereof. For example, the bottom surface of the semiconductor chip 100 may be an active surface.

The first via 120 may vertically penetrate the semiconductor chip 100. For example, the first via 120 may connect a top surface of the semiconductor chip 100 to the first circuit layer 110. The first via 120 and the first circuit layer 110 may be electrically connected to each other. The first via 120 may be provided in plural. A dielectric layer (not shown) may be provided as needed to surround the first via 120. For example, the dielectric layer (not shown) may include at least one selected from silicon oxide (SiO), silicon nitride (SiN), silicon oxynitride (SiON), and low-k dielectric layers, but example embodiments are not limited thereto.

The first upper pad 130 may be disposed on the top surface of the semiconductor chip 100. The first upper pad 130 may be coupled to the first via 120. The first upper pad 130 may be provided in plural. In some example embodiments, the plurality of first upper pads 130 may be correspondingly coupled to a plurality of first vias 120, and an arrangement of the first upper pads 130 may conform to that of the first vias 120. The first upper pad 130 may be coupled through the first via 120 to the first circuit layer 110. The first upper pad 130 may include a metallic material, such as one or more of copper (Cu), aluminum (Al), nickel (Ni), and any other suitable element.

The first protection layer 140 may be disposed on the top surface of the semiconductor chip 100 to surround the first upper pad 130. The first protection layer 140 may expose the first upper pad 130. The first protection layer 140 may protect the semiconductor chip 100. The first protection layer 140 may be a dielectric coating layer including epoxy resin.

The first lower pad 150 may be disposed on the bottom surface of the semiconductor chip 100. For example, the first lower pad 150 may be disposed on a bottom surface of the first circuit layer 110. The first lower pad 150 may be electrically connected to the first circuit layer 110. The first lower pad 150 may be provided in plural. The first lower pad 150 may include a metallic material, such as one or more of copper (Cu), aluminum (Al), nickel (Ni), and any other suitable element.

Although not shown, the semiconductor chip 100 may further include a lower protection layer (not shown). The lower protection layer (not shown) may be disposed on the bottom surface of the semiconductor chip 100 to cover the first circuit layer 110. The lower protection layer (not shown) may protect the first circuit layer 110. The lower protection layer (not shown) may include a silicon nitride (SiN) layer.

An external terminal 160 may be provided on the bottom surface of the semiconductor chip 100. The external terminal 160 may be disposed on the first lower pad 150. The external terminal 160 may be electrically connected to the first circuit layer 110 and the first via 120. Alternatively, the external terminal 160 may be disposed below the first via 120. In some example embodiments, the first via 120 may penetrate the first circuit layer 110 and may be exposed on the bottom surface of the first circuit layer 110, and the external terminal 160 may be directly coupled to the first via 120. The external terminal 160 may be provided in plural. In some example embodiments, the plurality of external terminals 160 may be correspondingly coupled to a plurality of first lower pads 150. The external terminal 160 may be an alloy that includes at least one selected from tin (Sn), silver (Ag), copper (Cu), nickel (Ni), bismuth (Bi), indium (In), antimony (Sb), and cerium (Ce), but example embodiments are not limited thereto.

The first chip stack CS1 may be disposed on the semiconductor chip 100. The first chip stack CS1 may be a lower chip stack. The first chip stack CS1 may include a plurality of first semiconductor chips 201, 202, and 203. The first semiconductor chips 201, 202, and 203 may be lower semiconductor chips. The first semiconductor chips 201, 202, and 203 may be of the same or substantially the same type. For example, the first semiconductor chips 201, 202, and 203 may be memory chips.

The first chip stack CS1 may include a first lower semiconductor chip 201 directly connected to the semiconductor chip 100, first intermediate semiconductor chips 202 disposed on the first lower semiconductor chip 201, and a first upper semiconductor chip 203 disposed on the first intermediate semiconductor chips 202. The first lower semiconductor chip 201, the first intermediate semiconductor chips 202, and the first upper semiconductor chip 203 may be sequentially stacked on the semiconductor chip 100. The first lower semiconductor chip 201 may be a lowermost semiconductor chip. The first intermediate semiconductor chips 202 may be stacked on each other between the first lower semiconductor chip 201 and the first upper semiconductor chip 203.

In some example embodiments, four first intermediate semiconductor chips 202 may be interposed between the first lower semiconductor chip 201 and the first upper semiconductor chip 203, but the inventive concepts are not limited thereto. In another example embodiment, less than three or more than five first intermediate semiconductor chips 202 may be interposed between the first lower semiconductor chip 201 and the first upper semiconductor chip 203, or none of the first intermediate semiconductor chips 202 may be provided between the first lower semiconductor chip 201 and the first upper semiconductor chip 203.

The first lower semiconductor chip 202 may have a second circuit layer 210 that faces the semiconductor chip 100. The second circuit layer 210 may include the integrated circuit. For example, the second circuit layer 210 may include a memory circuit. In some example embodiments, a bottom surface of the first lower semiconductor chip 201 may be an active surface.

The first lower semiconductor chip 201 may have a second protection layer 240 that stands opposite to the second circuit layer 210. The second protection layer 240 may protect the first lower semiconductor chip 201. The second protection layer 240 may be a dielectric coating layer including epoxy resin.

The first lower semiconductor chip 201 may have a second via 220 that penetrates a portion of the first lower semiconductor chip 201 in a direction from the second protection layer 240 toward the second circuit layer 210. The second via 220 may be provided in plural. A dielectric layer (not shown) may be provided to surround the second via 220. For example, the dielectric layer (not shown) may include at least one selected from silicon oxide (SiO), silicon nitride (SiN), silicon oxynitride (SiON), and low-k dielectric layers, but example embodiments are not limited thereto. The second via 220 may be electrically connected to the second circuit layer 210.

A second upper pad 230 may be disposed in the second protection layer 240. The second upper pad 230 may have a top surface that is exposed by the second protection layer 240. The second upper pad 230 may be connected to the second via 220. A second lower pad 250 may be disposed on the second protection layer 210. For example, the second lower pad 250 may be disposed on a bottom surface of the second circuit layer 210. The second lower pad 250 may be coupled to the second circuit layer 210. The second upper pad 230 and the second lower pad 250 may be electrically connected to each other through the second circuit layer 210 and the second via 220. The second upper pad 230 and the second lower pad 250 may each be provided in plural. The second upper pad 230 and the second lower pad 250 may include a metallic material, such as one or more of copper (Cu), aluminum (Al), nickel (Ni), and any other suitable element.

The first intermediate semiconductor chips 202 may have substantially the same or substantially the same structure as that of the first lower semiconductor chip 201. For example, each of the first intermediate semiconductor chips 202 may include a second circuit layer 210 that faces the semiconductor chip 100, a second protection layer 240 that stands opposite to the second circuit layer 210, a second via 220 that penetrates the first intermediate semiconductor chips 202 in a direction from the second protection layer 240 toward the second circuit layer 210, a second upper pad 230 in the second protection layer 240, and a second lower pad 250 on the second circuit layer 210.

The first upper semiconductor chip 203 may have a structure substantially similar to that of the first lower semiconductor chip 201. For example, the first upper semiconductor chip 203 may include a second circuit layer 210 that faces the semiconductor chip 100, a second protection layer 240 that stands opposite to the second circuit layer 210, a second via 220 that penetrates the first intermediate semiconductor chips 202 in a direction from the second protection layer 240 toward the second circuit layer 210, a second upper pad 230 in the second protection layer 240, and a second lower pad 250 on the second circuit layer 210.

The second chip stack CS2 may be disposed on the first upper semiconductor chip 203. The second chip stack CS2 may be an upper chip stack. The first upper semiconductor chip 203 may include a second circuit layer 210 that faces the semiconductor chip 100, a second protection layer 240 that stands opposite to the second circuit layer 210, a second via 220 that penetrates the first upper semiconductor chip 203 in a direction from the second protection layer 240 toward the second circuit layer 210, a second upper pad 230 in the second protection layer 240, and a second lower pad 250 on the second circuit layer 210.

The second chip stack CS2 may include a plurality of second semiconductor chips 301, 302, and 303. The second semiconductor chips 301, 302, and 303 may be of the same or substantially the same type of the first semiconductor chips 201, 202, and 203. The second semiconductor chips 301, 302, and 303 may be upper semiconductor chips. For example, the second semiconductor chips 301, 302, and 303 may be memory chips.

The second chip stack CS2 may include a second lower semiconductor chip 301 directly connected to the first upper semiconductor chip 203, second intermediate semiconductor chips 302 disposed on the second lower semiconductor chip 301, and a second upper semiconductor chip 303 disposed on the second intermediate semiconductor chips 302. The second lower semiconductor chip 301, the second intermediate semiconductor chips 302, and the second upper semiconductor chip 303 may be sequentially stacked on the first upper semiconductor chip 203. The second intermediate semiconductor chips 302 may be stacked on each other between the second lower semiconductor chip 301 and the second upper semiconductor chip 303.

In some example embodiments, four second intermediate semiconductor chips 302 may be interposed between the second lower semiconductor chip 301 and the second upper semiconductor chip 303, but the inventive concepts are not limited thereto. In another example embodiment, less than three or more than five second intermediate semiconductor chips 302 may be interposed between the second lower semiconductor chip 301 and the second upper semiconductor chip 303, or none of the second intermediate semiconductor chips 302 may be provided between the second lower semiconductor chip 301 and the second upper semiconductor chip 303.

The second semiconductor chips 301, 302, and 303 may have substantially the same structure as that of the first semiconductor chips 201, 202, and 203. For example, the second lower semiconductor chip 301 and the second intermediate semiconductor chips 302 may each include a third circuit layer 310 that faces the first chip stack CS1, a third protection layer 340 that stands opposite to the third circuit layer 310, a third via 320 that penetrates the second lower semiconductor chip 301 in a direction from the third protection layer 340 toward the third circuit layer 310, a third upper pad 330 in the third protection layer 340, and a third lower pad 350 on the third circuit layer 310. The second upper semiconductor chip 303 may include a third circuit layer 310 that faces the first chip stack CS1 and a third lower pad 350 on the third circuit layer 310.

The second upper semiconductor chip 303 may include none of the third via 320, the third upper pad 330, and the third protection layer 340. The inventive concepts, however, are not limited thereto. The second upper semiconductor chip 303 may have a thickness greater than that of the second lower semiconductor chip 301 and those of the second intermediate semiconductor chips 302.

Chip terminals 460 may be provided to connect the semiconductor chip 100 to the first lower semiconductor chip 201, neighboring first semiconductor chips 201, 202, and 203 to each other, the first upper semiconductor chip 203 to the second lower semiconductor chip 301, and neighboring second semiconductor chips 301, 302, and 303 to each other. The chip terminals 460 may be solder balls each of which is formed of an alloy including at least one selected from tin (Sn), silver (Ag), copper (Cu), nickel (Ni), bismuth (Bi), indium (In), antimony (Sb), and cerium (Ce), but example embodiments are not limited thereto. The chip terminals 460 may electrically connect the semiconductor chip 100 to the first lower semiconductor chip 201, neighboring first semiconductor chips 201, 202, and 203 to each other, the first upper semiconductor chip 203 to the second lower semiconductor chip 301, and neighboring second semiconductor chips 301, 302, and 303 to each other.

Thermal conductive layers 410 and 420 may be provided between the semiconductor chip 100 and the first lower semiconductor chip 201, between neighboring first semiconductor chips 201, 202, and 203, and between neighboring second semiconductor chips 301, 302, and 303. The thermal conductive layers 410 and 420 may include first thermal conductive layers 410 and second thermal conductive layers 420. The first thermal conductive layers 410 may be respectively disposed between the semiconductor chip 100 and the first chip stack CS1 and between neighboring first semiconductor chips 201, 202, and 203. The second thermal conductive layers 420 may be respectively disposed between the first chip stack CS1 and the second chip stack CS2 and between neighboring second semiconductor chips 301, 302, and 303.

The first thermal conductive layers 410 may fill a space between the semiconductor chip 100 and the first lower semiconductor chip 201 and spaces between neighboring first semiconductor chips 201, 202, and 203. The second thermal conductive layers 420 may fill a space between the first chip stack CS1 and the second chip stack CS2 and spaces between neighboring second semiconductor chips 301, 302, and 303. For example, the first thermal conductive layers 410 and the second thermal conductive layers 420 may each serve as an under-fill layer that fills a space between semiconductor chips, and may thus increase mechanical durability of the chip terminals 460.

The thermal conductive layers 410 and 420 may surround the chip terminals 460. The chip terminals 460 may have their lateral surfaces in contact with the first thermal conductive layers 410 or the second thermal conductive layers 420. The thermal conductive layers 410 and 420 may have their lateral surfaces substantially aligned with those of the first semiconductor chips 201, 202, and 203 and those of the second semiconductor chips 301, 302, and 303.

The first thermal conductive layers 410 may include a first thermal interface material. The second thermal conductive layers 420 may include a second thermal interface material. The first thermal interface material may have a thermal conductivity different from that of the second thermal interface material. The thermal conductivity of the second thermal interface material may be greater than that of the first thermal interface material. For example, the thermal conductivity of the first thermal interface material may be in a range from about 2 W/mK to about 5 W/mK, and the thermal conductivity of the second thermal interface material may be in a range from about 10 W/mK to about 15 W/mK. The first thermal interface material may have a stiffness different from that of the second thermal interface material. For example, the stiffness of the first thermal interface material may be greater than that of the second thermal interface material.

For example, the first thermal interface material and the second thermal interface material may include a resin and a filler. The filler may include aluminum oxide (Al₂O₃) or aluminum nitride (AlN). The filler of the first thermal interface material may have an amount in a range of about 20 vol % to about 50 vol %. The filler of the second thermal interface material may have an amount in a range of about 80 vol % to about 97 vol %. For example, the filler of the second thermal interface material may have an amount in a range of about 90 vol % to about 92 vol %.

Referring to FIGS. 2 to 4, an increase in amount of a filler FL in a resin RS may lead to an increase in thermal conductivity. Referring to FIGS. 2 and 3, an increase in amount of the filler FL in the resin RS may cause an increase in contact area between the fillers FL, and thus heat may be readily transferred to achieve a high thermal conductivity. A reduction in amount of the filler FL in the resin RS may cause a decrease in contact area between the fillers FL, and thus heat may be hardly transferred to achieve a low thermal conductivity. When the resin RS has a small amount of the filler FL, a thermal interface material may have a large stiffness. Referring to FIG. 4, when the filler FL includes aluminum oxide (Al₂O₃) or aluminum nitride (AlN) and has an amount greater than about 80%, a thermal conductivity may abruptly increase.

The second thermal conductive layers 420 positioned in an upper portion may have a thermal conductivity greater than that of the first thermal conductive layers 410, and thus heat may be easily discharged from the semiconductor package 1. The semiconductor package 1 may therefore increase in thermal stability. In addition, the first thermal conductive layers 410 positioned in a lower portion may have a stiffness greater than that of the second thermal conductive layers 420, the semiconductor package 1 may thus increase in structural stability.

Referring still to FIG. 1, a molding layer 500 may be provided on the semiconductor chip 100. The molding layer 500 may cover the top surface of the semiconductor chip 100. A lateral surface of the molding layer 500 may be aligned with that of the semiconductor chip 100. The molding layer 500 may cover the first chip stack CS1 and the second chip stack CS2. For example, the molding layer 500 may cover the lateral surfaces of the first semiconductor chips 201, 202, and 203 and the lateral surfaces of the second semiconductor chips 301, 302, and 303. The molding layer 500 may include a dielectric material. For example, the molding layer 500 may include an epoxy molding compound (EMC).

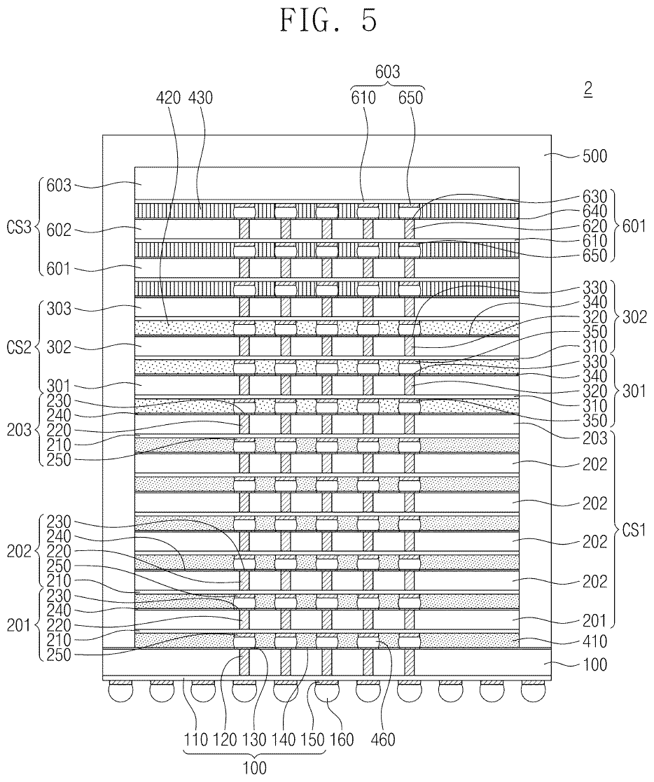

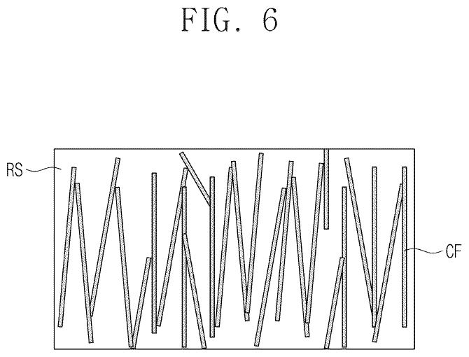

FIG. 5 illustrates a cross-sectional view showing a semiconductor package according to some example embodiments of the inventive concepts. FIG. 6 illustrates a conceptual diagram showing a thermal interface material according to some example embodiments of the inventive concepts. A duplicate description will be omitted below.

Referring to FIG. 5, a semiconductor package 2 may include a base substrate 100, a first chip stack CS1, a second chip stack CS2, a third chip stack CS3, a first thermal conductive layer 410, a second thermal conductive layer 420, and a third thermal conductive layer 430.

The third chip stack CS3 may be disposed on a second upper semiconductor chip 303. The second upper semiconductor chip 303 may include a third circuit layer 310 that faces the first chip stack CS1, a third protection layer 340 that stands opposite to the third circuit layer 310, a third via 320 that penetrates a second lower semiconductor chip 301 in a direction from the third protection layer 340 toward the third circuit layer 310, a third upper pad 330 in the third protection layer 340, and a third lower pad 350 on the third circuit layer 310.

The third chip stack CS3 may include a plurality of third semiconductor chips 601, 602, and 603. The number of the third semiconductor chips 601, 602, and 603 may be equal to or less than about 30% of that of semiconductor chips in the semiconductor package 2. The third semiconductor chips 601, 602, and 603 may be of the same or substantially the same type of the first semiconductor chips 201, 202, and 203. For example, the third semiconductor chips 601, 602, and 603 may be memory chips.

The third chip stack CS3 may include a third lower semiconductor chip 601 directly connected to the second upper semiconductor chip 303, third intermediate semiconductor chips 602 disposed on the third lower semiconductor chip 601, and a third upper semiconductor chip 603 disposed on the third intermediate semiconductor chips 602. The third lower semiconductor chip 601, the third intermediate semiconductor chips 602, and the third upper semiconductor chip 603 may be sequentially stacked on the second upper semiconductor chip 303. The third intermediate semiconductor chips 602 may be stacked on each other between the third lower semiconductor chip 601 and the third upper semiconductor chip 603. In another embodiment, more than two third intermediate semiconductor chips 602 may be interposed between the third lower semiconductor chip 601 and the third upper semiconductor chip 603.

The third semiconductor chips 601, 602, and 603 may have substantially the same or substantially the same structure as that of the first semiconductor chips 201, 202, and 203. For example, the third lower semiconductor chip 601 and the third intermediate semiconductor chips 602 may each include a third circuit layer 610 that faces the second chip stack CS2, a third protection layer 640 that stands opposite to the third circuit layer 610, a third via 620 that penetrates the third lower semiconductor chip 601 in a direction from the third protection layer 640 toward the third circuit layer 610, a third upper pad 630 in the third protection layer 640, and a third lower pad 650 on the third circuit layer 610. The third upper semiconductor chip 603 may include a third circuit layer 610 that faces the second chip stack CS2 and a third lower pad 650 on the third circuit layer 610. The third upper semiconductor chip 603 may include none of the third via 620, the third upper pad 630, and the third protection layer 640.

The inventive concepts, however, are not limited thereto. The third upper semiconductor chip 603 may have a thickness greater than that of the third lower semiconductor chip 601 and those of the third intermediate semiconductor chips 602. The second upper semiconductor chip 303 and the third lower semiconductor chip 601 may be connected to each other through chip terminals 460, and neighboring ones of the third semiconductor chips 601, 602, and 603 may be connected to each other through chip terminals 460.

The third thermal conductive layers 430 may be respectively provided between the second chip stack CS2 and the third chip stack CS3 and between neighboring ones of the third semiconductor chips 601, 602, and 603. The third thermal conductive layers 430 may fill a space between the second chip stack CS2 and the third chip stack CS3 and spaces between neighboring third semiconductor chips 601, 602, and 603. The third thermal conductive layers 430 may surround the chip terminals 460. The chip terminals 460 may have their lateral surfaces in contact with the first thermal conductive layers 410, the second thermal conductive layers 420, or the third thermal conductive layers 430.

The third thermal conductive layers 430 may include a third thermal interface material. The third thermal interface material may include a resin and a carbon fiber. The third thermal interface material may have a thermal conductivity greater than that of the first thermal interface material and that of the second thermal interface material. The thermal conductivity of the third thermal interface material may be in a range from about 10 W/mK to about 20 W/mK.

Referring to FIG. 6, when the resin RS includes the carbon fiber CF therein, the carbon fiber CF may be aligned in the same or substantially the same direction, and thus heat may be readily transferred to achieve a high thermal conductivity.

Because the thermal conductivity of the third thermal conductive layers 430 positioned on the first and second thermal conductive layers 410 and 420 is greater than that of the first thermal conductive layers 410 and that of the second thermal conductive layers 420, heat may be easily discharged from the semiconductor package 2. The semiconductor package 2 may therefore increase in thermal stability.

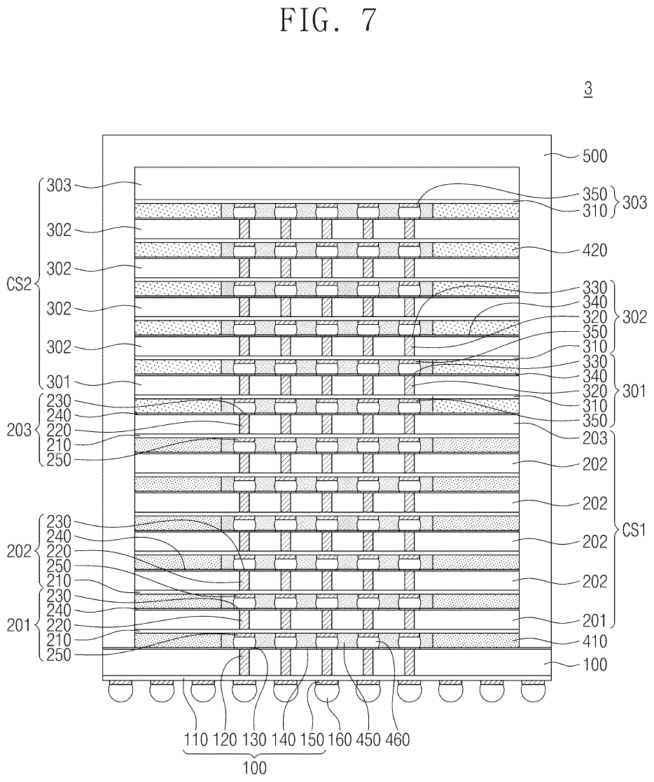

FIG. 7 illustrates a cross-sectional view showing a semiconductor package according to some example embodiments of the inventive concepts. A duplicate description will be omitted below.

Referring to FIG. 7, a semiconductor package 3 may include a base substrate 100, a first chip stack CS1, a second chip stack CS2, first thermal conductive layers 410, second thermal conductive layers 420, non-conductive layers 450, and chip terminals 460.

When viewed in plan, the chip terminals 460 may be positioned on central portions of the semiconductor chip 100, the first semiconductor chips 201, 202, and 203, and the second semiconductor chips 301, 302, and 303.

The non-conductive layers 450 may be provided between the semiconductor chip 100 and the first lower semiconductor chip 201, between neighboring first semiconductor chips 201, 202, and 203, and between neighboring second semiconductor chips 301, 302, and 303. The non-conductive layers 450 may surround the chip terminals 460. The chip terminals 460 may have their lateral surfaces in contact with the non-conductive layers 450. When viewed in plan, the non-conductive layers 450 may be positioned on central portions of the semiconductor chip 100, the first semiconductor chips 201, 202, and 203, and the second semiconductor chips 301, 302, and 303. The non-conductive layers 450 may be interposed between the chip terminals 460 and the thermal conductive layers 410 and 420. The non-conductive layers 450 may fill spaces between the chip terminals 460.

The non-conductive layers 450 may include a non-conductive film (NCF) or a non-conductive paste (NCP). The non-conductive layers 450 may include a dielectric polymer. For example, the non-conductive layers 450 may be formed of an epoxy-based material that does not contain a conductive particle. Therefore, the non-conductive layers 450 may inhibit or prevent electric short-circuits between neighboring chip terminals 460. In addition, the non-conductive layers 450 may serve as under-fill layers that fill spaces between semiconductor chips, and may thus increase in mechanical durability of the chip terminals 460.

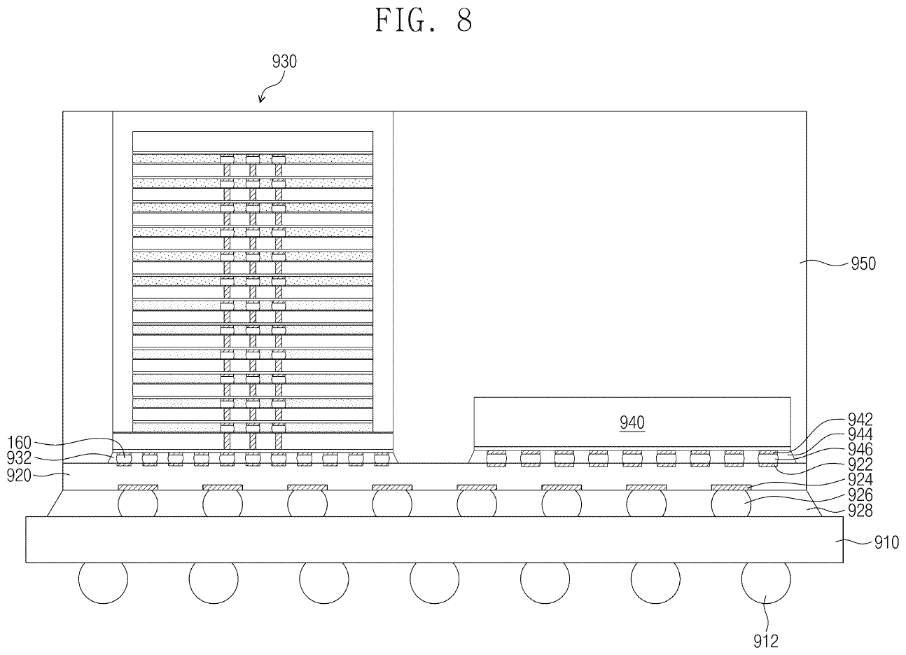

FIG. 8 illustrates a cross-sectional view showing a semiconductor module according to some example embodiments of the present inventive concepts.

Referring to FIG. 8, a semiconductor module may be, for example, a memory module including a module substrate 910, a chip stack package 930 and a graphic processing unit (GPU) 940 that are mounted on the module substrate 910, and an outer molding layer 950 that covers the chip stack package 930 and the graphic processing unit 940. The semiconductor module may further include an interposer 920 provided on the module substrate 910.

The module substrate 910 may be provided. The module substrate 910 may include a printed circuit board (PCB) having a signal pattern on a top surface thereof.

The module substrate 910 may be provided with module terminals 912 thereunder. The module substrate 910 may include solder balls or solder bumps, and based on type of the module substrate 910, the semiconductor module may be provided in the shape of one of a ball grid array (BGA) type, a fine ball-grid array (FBGA) type, and a land grid array (LGA) type, but example embodiments are not limited thereto.

The interposer 920 may be provided on the module substrate 910. The interposer 920 may include first substrate pads 922 exposed on a top surface of the interposer 920 and second substrate pads 924 exposed on a bottom surface of the interposer 920. The interposer 920 may redistribute the chip stack package 930 and the graphic processing unit 940. The interposer 920 may be flip-chip mounted on the module substrate 910. For example, the interposer 920 may be mounted on the module substrate 910 through substrate terminals 926 provided on the second substrate pads 924. The substrate terminals 926 may include solder balls or solder bumps. A first under-fill layer 928 may be provided between the module substrate 910 and the interposer 920.

The chip stack package 930 may be disposed on the interposer 920. The chip stack package 930 may have a structure the same as or similar to that of the semiconductor package discussed with reference to FIGS. 1 to 7.

The chip stack package 930 may be mounted on the interposer 920. For example, the chip stack package 930 may be coupled to the first substrate pads 922 of the interposer 920 through the external terminals 160 of the semiconductor chip 100. A second under-fill layer 932 may be provided between the chip stack package 930 and the interposer 920. The second under-fill layer 932 may surround the external terminals 160 of the semiconductor chip 100, while filling a space between the interposer 920 and the semiconductor chip 100.

The graphic processing unit 940 may be disposed on the interposer 920. The graphic processing unit 940 may be disposed spaced apart from the chip stack package 930. The graphic processing unit 940 may have a thickness greater than those of the semiconductor chips 100, 201, 202, 203, 301, 302, and 303 of the chip stack package 930. The graphic processing unit 940 may include a logic circuit. For example, the graphic processing unit 940 may be a logic chip. The graphic processing unit 940 may be provided with pads 942 on a bottom surface thereof. For example, the graphic processing unit 940 may be coupled through the bumps 946 to the first substrate pads 922 of the interposer 920. A third under-fill layer 944 may be provided between the interposer 920 and the graphic processing unit 940. The third under-fill layer 944 may surround the bumps 942, while filling a space between the interposer 920 and the graphic processing unit 940.

The outer molding layer 950 may be provided on the interposer 920. The outer molding layer 950 may cover the top surface of the interposer 920. The outer molding layer 950 may encapsulate the chip stack package 930 and the graphic processing unit 940. The outer molding layer 950 may have a top surface located at the same or substantially the same level as that of a top surface of the chip stack package 930. The outer molding layer 950 may include a dielectric material. For example, the outer molding layer 950 may include an epoxy molding compound (EMC).

In a semiconductor package according to some example embodiments of the inventive concepts, a lower thermal conductive layer may include a thermal interface material having a lower thermal conductivity and a higher stiffness than those of a thermal interface material included in an upper thermal conductive layer, and thus it may be possible to easily discharge heat generated from the semiconductor package and to increase durability of the semiconductor package. Accordingly, the semiconductor package may increase in thermal and structural stability.

It will be understood that elements and/or properties thereof described herein as being “substantially” the same and/or identical encompasses elements and/or properties thereof that have a relative difference in magnitude that is equal to or less than 10%. Further, regardless of whether elements and/or properties thereof are modified as “substantially,” it will be understood that these elements and/or properties thereof should be construed as including a manufacturing or operational tolerance (e.g., ±10%) around the stated elements and/or properties thereof.

When the terms “about” or “substantially” are used in this specification in connection with a numerical value, it is intended that the associated numerical value include a tolerance of ±10% around the stated numerical value. When ranges are specified, the range includes all values therebetween such as increments of 0.1%.

One or more of the elements disclosed above may include or be implemented in one or more processing circuitries such as hardware including logic circuits; a hardware/software combination such as a processor executing software; or a combination thereof. For example, the processing circuitries more specifically may include, but is not limited to, a central processing unit (CPU), an arithmetic logic unit (ALU), a digital signal processor, a microcomputer, a field programmable gate array (FGPA), a System-on-Chip (SoC), a programmable logic unit, a microprocessor, application-specific integrated circuit (ASIC), etc.

Although the inventive concepts have been described in connection with the some example embodiments of the inventive concepts illustrated in the accompanying drawings, it will be understood by one of ordinary skill in the art that variations in form and detail may be made therein without departing from the scope of the inventive concepts. The above disclosed example embodiments should thus be considered illustrative and not restrictive.

What is claimed is:

1. A semiconductor package, comprising:
a substrate including a plurality of vias;
a first chip stack on the substrate, the first chip stack including a plurality of first semiconductor chips sequentially stacked on the substrate;
a second chip stack on the first chip stack, the second chip stack including a plurality of second semiconductor chips sequentially stacked on the first chip stack;
a plurality of first thermal conductive layers, a first one of the plurality of first thermal conductive layers between the substrate and the first chip stack, and at least a second one of the plurality of first thermal conductive layers between first semiconductor chips that are adjacent to each other; and
a plurality of second thermal conductive layers, a first one of the plurality of second thermal conductive layers between the first chip stack and the second chip stack, and at least a second one of the plurality of second thermal conductive layers between second semiconductor chips that are adjacent to each other,
wherein the first thermal conductive layers include a first thermal interface material,
wherein the second thermal conductive layers include a second thermal interface material,
wherein a thermal conductivity of the second thermal interface material is greater than a thermal conductivity of the first thermal interface material, and
wherein a stiffness of the first thermal interface material is greater than a stiffness of the second thermal interface material.

2. The semiconductor package of claim 1, wherein
the first thermal interface material and the second thermal interface material include a filler, and
an amount of the filler in the second thermal interface material is greater than an amount of the filler in the first thermal interface material.

3. The semiconductor package of claim 2, wherein the filler includes aluminum oxide or aluminum nitride.

4. The semiconductor package of claim 2, wherein
an amount of the filler in the first thermal interface material is in a range of 20 vol % to 50 vol %, and
an amount of the filler in the second thermal interface material is in a range of 80 vol % to 97 vol %.

5. The semiconductor package of claim 2, wherein
an amount of the filler in the first thermal interface material is in a range of 20 vol % to 50 vol %, and
an amount of the filler in the second thermal interface material is in a range of 90 vol % to 92 vol %.

6. The semiconductor package of claim 1, wherein
a thermal conductivity of the first thermal interface material is in a range of 2 W/mK to 5 W/mK, and
a thermal conductivity of the second thermal interface material is in a range of 10 W/mK to 15 W/mK.

7. The semiconductor package of claim 1, further comprising:
a third chip stack on the second chip stack, the third chip stack including a plurality of third semiconductor chips sequentially stacked on the second chip stack; and
a plurality of third thermal conductive layers, a first one of the plurality of third thermal conductive layers between the second chip stack and the third chip stack, and at least a second one of the plurality of third thermal conductive layers between third semiconductor chips that are adjacent to each other,
wherein the third thermal conductive layers include a third thermal interface material, and
wherein the third thermal interface material includes a carbon fiber.

8. The semiconductor package of claim 7, wherein a thermal conductivity of the third thermal interface material is in a range of 10 W/mK to 20 W/mK.

9. The semiconductor package of claim 1, wherein
the substrate is a silicon wafer, and
each of the first semiconductor chips and second semiconductor chips is a memory chip.

10. The semiconductor package of claim 1, further comprising a molding layer on the substrate, the molding layer covering the first chip stack and the second chip stack.

11. The semiconductor package of claim 1, further comprising a plurality of chip terminals, each of the plurality of chip terminals between a corresponding one of
the substrate and the first chip stack,
first semiconductor chips that are adjacent to each other,
the first chip stack and the second chip stack, or
second semiconductor chips that are adjacent to each other,
wherein lateral surfaces of the chip terminals are in contact with a corresponding one of the first thermal conductive layers or the second thermal conductive layers.

12. A semiconductor package, comprising:
a substrate;
a plurality of semiconductor chips sequentially stacked on the substrate;
a plurality of chip terminals connecting the substrate to a lowermost one of the semiconductor chips and connecting neighboring semiconductor chips to each other, the chip terminals on central portions of the semiconductor chips with respect to a plan view;
a plurality of non-conductive layers surrounding the chip terminals; and
a plurality of thermal conductive layers, a first one of the plurality of thermal conductive layers between the substrate and the lowermost one of the semiconductor chips, and at least a second one of the plurality of thermal conductive layers between semiconductor chips that are adjacent to each other,
wherein the thermal conductive layers include
a plurality of first thermal conductive layers, a first one of the plurality of first thermal conductive layers between the substrate and the lowermost one of the semiconductor chips, and at least a second one of the plurality of first thermal conductive layers between lower ones of the semiconductor chips; and
a plurality of second thermal conductive layers between upper ones of the semiconductor chips,
wherein a thermal conductivity of the second thermal conductive layers is greater than a thermal conductivity of the first thermal conductive layers.

13. The semiconductor package of claim 12, wherein the non-conductive layers include a non-conductive film or a non-conductive paste.

14. The semiconductor package of claim 12, wherein the non-conductive layers are between the chip terminals and the thermal conductive layers.

15. The semiconductor package of claim 14, wherein lateral surfaces of the chip terminals are in contact with the non-conductive layers.

16. The semiconductor package of claim 13, wherein
the first thermal conductive layers include a first thermal interface material,
the second thermal conductive layers include a second thermal interface material,
the first thermal interface material and the second thermal interface material include a filler, and
the filler includes aluminum oxide or aluminum nitride.

17. The semiconductor package of claim 16, wherein an amount of the filler in the second thermal interface material is greater than an amount of the filler in the first thermal interface material.

18. The semiconductor package of claim 16, wherein
an amount of the filler in the first thermal interface material is in a range of 20 vol % to 50 vol %, and
an amount of the filler in the second thermal interface material is in a range of 80 vol % to 97 vol %.

19. A semiconductor package, comprising:
a substrate including a plurality of vias;
a first chip stack mounted on the substrate, the first chip stack including a plurality of first semiconductor chips sequentially stacked on the substrate;
a second chip stack mounted on a top surface of the first chip stack, the second chip stack including a plurality of second semiconductor chips sequentially stacked on the first chip stack;
a plurality of first thermal conductive layers, a first one of the plurality of first thermal conductive layers between the substrate and the first chip stack, and at least a second one of the plurality of first thermal conductive layers between first semiconductor chips that are adjacent to each other, the first thermal conductive layers including a first thermal interface material;
a plurality of second thermal conductive layers, a first one of the plurality of second thermal conductive layers between the first chip stack and the second chip stack, and at least a second one of the plurality of second thermal conductive layers between second semiconductor chips that are adjacent to each other, the second thermal conductive layers including a second thermal interface material; and
a molding layer on the substrate, the molding layer covering the first chip stack and the second chip stack,
wherein the first thermal interface material and the second thermal interface material include aluminum oxide,
wherein an amount of the aluminum oxide in the second thermal interface material is greater than an amount of the aluminum oxide in the first thermal interface material.

20. The semiconductor package of claim 19, wherein
the amount of the aluminum oxide in the first thermal interface material is in a range of 20 vol % to 50 vol %, and
the amount of the aluminum oxide in the second thermal interface material is in a range of 80 vol % to 97 vol %.
